(19) United States
(12) Patent Application Publication
(10) Pub. No.: US 2024/0429193 A1
(43) Pub. Date: Dec. 26, 2024

(54) ELECTRONIC DEVICE

(71) Applicant: InnoLux Corporation, Miao-Li County (TW)

(72) Inventors: Pei-Yin CHOU, Miao-Li County (TW); Te-Hsun LIN, Miao-Li County (TW); Wen-Hsiang LIAO, Miao-Li County (TW)

(21) Appl. No.: 18/668,786

(22) Filed: May 20, 2024

Related U.S. Application Data
(60) Provisional application No. 63/509,293, filed on Jun. 21, 2023.

(30) Foreign Application Priority Data
Mar. 22, 2024 (CN) 202410334240.9

(51) Int. Cl. H01L 23/00; H01L 23/31

(52) U.S. Cl. CPC H01L 24/20; H01L 23/3135; H01L 2224/2101; H01L 2224/215

(57) ABSTRACT

An electronic device is provided. The electronic device includes an electronic component, an encapsulating layer, a circuit structure, a bonding element and a first auxiliary pad. The encapsulating layer surrounds the electronic component. The circuit structure is electrically connected to the electronic component. The circuit structure has a connection part. The bonding element overlaps with the connection part and is electrically connected to the electronic component. The first auxiliary pad is disposed in the circuit structure. In addition, the connection part is disposed between the first auxiliary pad and the bonding element, and the connection part overlaps with the first auxiliary pad. Moreover, the intrinsic stress of the first auxiliary pad is between +800 MPa and −1000 MPa.

### CROSS REFERENCE TO RELATED APPLICATIONS

This application claims the benefit of China Application No. 202410334240.9, filed Mar. 22, 2024, and U.S. Provisional Application No. 63/509,293, filed Jun. 21, 2023, the entirety of which are incorporated by reference herein.

### BACKGROUND

### Technical Field

The present disclosure is related to an electronic device, and in particular it is related to an electronic device having a package structure.

### Description of the Related Art

Fan-out packaging, such as fan-out panel level package (FOPLP) or fan-out wafer level package (FOWLP) technology, can increase the integration density of electronic components (e.g., transistors, diodes, resistors, capacitors, etc.) in a given area. It has been widely used in the production and manufacturing of electronic devices in recent years.

However, a fan-out packaging structure has many interface integration structures of heterogeneous materials (for example, the interface between the redistribution layer (RDL) and the conductive pad, or under bump metallurgy (UBM) area, etc.), and the interface between heterogeneous materials is prone to problems such as delamination or peeling due to the presence of large amounts of stress.

As described above, developing packaging structures that can improve the reliability of electronic devices (for example, improving the strength of the connection structure between interfaces) is still one of the current research topics in the industry.

### SUMMARY

In accordance with some embodiments of the present disclosure, an electronic device is provided. The electronic device includes an electronic component, an encapsulating layer, a circuit structure, a bonding element and a first auxiliary pad. The encapsulating layer surrounds the electronic component. The circuit structure is electrically connected to the electronic component. The circuit structure has a connection part. The bonding element overlaps with the connection part and is electrically connected to the electronic component. The first auxiliary pad is disposed in the circuit structure. In addition, the connection part is disposed between the first auxiliary pad and the bonding element, and the connection part overlaps with the first auxiliary pad. Moreover, the intrinsic stress of the first auxiliary pad is between +800 MPa and −1000 MPa.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a cross-sectional diagram of an electronic device in accordance with some embodiments of the present disclosure;

FIGS. 2A to 2F are cross-sectional diagrams of an electronic device during the intermediate stages of the manufacturing process in accordance with some embodiments of the present disclosure;

FIG. 3 is a cross-sectional diagram of an electronic device in accordance with some embodiments of the present disclosure;

FIG. 4 is a cross-sectional diagram of an electronic device in accordance with some embodiments of the present disclosure;

FIG. 5 is a cross-sectional diagram of an electronic device in accordance with some embodiments of the present disclosure;

FIG. 6 is a top-view diagram of an electronic device in accordance with some embodiments of the present disclosure.

### DETAILED DESCRIPTION

The electronic device and the method of manufacturing the same according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

It should be understood that, in accordance with the embodiments of the present disclosure, a scanning electron microscope (SEM), an optical microscope (OM), a film thickness profiler (α-step), an ellipsometer or another suitable method may be used to measure the width, thickness or height of each element, or the distance or spacing between elements. Specifically, in accordance with some embodiments, a scanning electron microscope may be used to obtain a cross-sectional image including the elements to be measured, and the width, thickness or height of each element, or the distance or spacing between elements in the image can be measured.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which the present disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with the embodiments of the present disclosure, an electronic device is provided, including an auxiliary pad disposed in a circuit structure. The auxiliary pad can improve the overall stress balance of the connection structures (for example, the connection parts and the bonding elements of the circuit structure) and reduce the stress in the vertical direction when the connection structures are joined, and thereby improving the packaging reliability of the electronic device.

In accordance with the embodiments of the present disclosure, the electronic device may include a power module, a semiconductor packaging device, a display device, a backlight device, an antenna device, a touch device, a sensing device, a wearable device, a vehicle device, a battery device, or a tiled device, but it is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device that senses capacitance, light, heat energy or ultrasonic waves, but it is not limited thereto. Furthermore, the electronic device may include, for example, liquid crystals, quantum dots (QDs), fluorescence, phosphorescence, another suitable material, or a combination thereof. The electronic device may include electronic components. The electronic components may include passive components and active components, such as capacitors, resistors, inductors, diodes, transistors, etc. The diode may include a light-emitting diode or a photodiode. The light-emitting diode may include, for example, an organic light-emitting diode (OLED), a mini light-emitting diode (mini LED), a micro light-emitting diode (micro LED) or a quantum dot light-emitting diode (quantum LED), but it is not limited thereto. In accordance with some embodiments, the electronic device may include a panel and/or a backlight module. The panel may include, for example, a liquid-crystal panel or another self-luminous panel, but it is not limited thereto. The tiled device may be, for example, a display tiled device or an antenna tiled device, but it is not limited thereto. It should be understood that the electronic device can be any permutation and combination of the above, but it is not limited thereto.

In accordance with the embodiments of the present disclosure, the provided method of manufacturing the electronic device can be applied, for example, to a wafer-level package (WLP) or panel-level package (PLP) process, and a chip-first process or a chip-last/RDL first process may be used, which will be explained in further detail below. The electronic device referred to in the present disclosure may include a system on package (SoC), a system in package (SiP), an antenna in package (AiP), or a combination thereof, but it is not limited thereto.

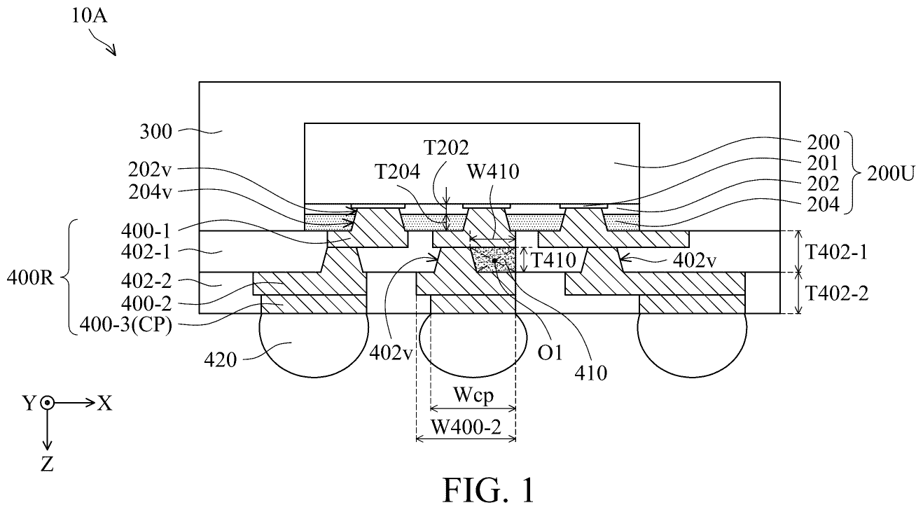

Please refer to FIG. 1, which is a cross-sectional diagram of an electronic device 10A in accordance with some embodiments of the present disclosure. It should be understood that, for clarity of explanation, some components of the electronic device 10A may be omitted in the drawings, and only some components are schematically illustrated. In accordance with some embodiments, additional features may be added to the electronic device 10A described below. In accordance with other embodiments, some features of the electronic device 10A described below may be replaced or omitted.

As shown in FIG. 1, the electronic device 10A includes an electronic component 200U, an encapsulating layer 300, a circuit structure 400R, a bonding element 420 and an auxiliary pad 410.

In accordance with some embodiments, the electronic component 200U includes a chip 200, a passivation layer 202, and an insulating layer 204. The passivation layer 202 may be disposed between the chip 200 and the insulating layer 204.

In accordance with some embodiments, the chip 200 may include, for example, a known-good die (KGD), an integrated circuit chip (IC), a surface mount device (SMD), a diode, a filters, a sensor, a microelectromechanical system components (MEMS), a liquid-crystal chip, a structure related to semiconductor processes, or a structure related to semiconductor processes or another suitable electronic component disposed on the substrate (such as polyimide, glass, silicon substrate or another suitable substrate material), but it is not limited thereto. The surface mount device may include a capacitor, a resistor, an inductor, etc., but it is not limited thereto.

In accordance with some embodiments, the passivation layer 202 is disposed on the surface of the chip 200 and in contact with the chip 200. In accordance with some embodiments, the passivation layer 202 has a through hole 202v and a conductive material is disposed in the through hole 202v. For example, the electronic component 200U may further include a conductive pad 201, and the passivation layer 202 may surround the conductive pad 201. The through hole 202v may expose at least a portion of the conductive pad 201, and the conductive material may be electrically connected to the conductive pad 201 through the through hole 202v. Moreover, the conductive pad 201 may be, for example, one end of a transistor (for example, a source, a gate or a drain). In accordance with some embodiments, the conductive material disposed in the through hole 202v can serve as a part of the patterned conductive layer 400-1 of the circuit structure 400R, and the circuit structure 400R is electrically connected to the chip 200 through the through hole 202v of the passivation layer 202. The passivation layer 202 may have a single-layer or multi-layer structure. Furthermore, the passivation layer 202 has a thickness T202. In accordance with some embodiments, the thickness T202 may be between 0.3 micrometers (μm) and 1.2 μm (0.3 μm≤the thickness T202≤1.2 μm), for example, 0.4 μm, 0.5 μm, 0.6 μm, 0.7 μm, 0.8 μm, 0.9 μm, 1 μm or 1.1 μm, but it is not limited thereto. In accordance with some embodiments, the thermal expansion coefficient (CTE) of the passivation layer 202 may be between 0.1 ppm/K and 10 ppm/K (0.1 ppm/K≤the thermal expansion coefficient of the passivation layer 202≤10 ppm/K), or between 1 ppm/K and 9 ppm/K, for example, 2 ppm/K, 3 ppm/K, 4 ppm/K, 5 ppm/K, 6 ppm/K, 7 ppm/K or 8 ppm/K, but it is not limited thereto. The thickness referred to in the present disclosure may be the maximum thickness of an element along the Z direction in the cross-sectional view.

The insulating layer 204 is disposed between the passivation layer 202 and the circuit structure 400R. In accordance with some embodiments, the insulating layer 204 is disposed on the surface of the passivation layer 202 and in contact with the passivation layer 202. The insulating layer 204 has a through hole 204v and a conductive material is disposed in the through hole 204v. The conductive material disposed in the through hole 204v can serve as a part of the patterned conductive layer 400-1, and the circuit structure 400R is electrically connected to the chip 200 by the through hole 204v of the insulating layer 204. The insulating layer 204 may have a single-layer or multi-layer structure. Furthermore, the insulating layer 204 has a thickness T204. In accordance with some embodiments, the thickness T204 may be between 5 μm and 25 μm (5 μm≤the thickness T204≤25 μm), or between 10 μm and 20 μm, for example, 11 μm, 12 μm, 13 μm, 14 μm, 15 μm, 16 μm, 17 μm, 18 μm or 19 μm, but it is not limited thereto. In accordance with some embodiments, the thermal expansion coefficient of the insulating layer 204 may be between 10 ppm/K and 50 ppm/K (10 ppm/K ≤ the thermal expansion coefficient of the insulating layer 204≤50 ppm/K), or between 15 ppm/K and 45 ppm/K, or between 20 ppm/K and 40 ppm/K, for example, 25 ppm/K, 30 ppm/K or 35 ppm/K, but it is not limited thereto. The thermal expansion coefficient referred to in the present disclosure can be measured by a thermomechanical analyzer. For example, a sample of 1 cm×1 cm (length of 1 cm and width of 1 cm) can be made for testing or a sample of appropriate size can be made according to the limitations of the instrument, but it is not limited thereto.

It should be noted that the thickness T204 of the insulating layer 204 is greater than the thickness T202 of the passivation layer 202. With this configuration, the insulating layer 204 can provide a buffering effect to reduce the risk of cracking of the electronic component 200U caused by the wafer cutting process (e.g., cutting to form chips). Furthermore, the aforementioned thickness T202 refers to the maximum thickness of the passivation layer 202 in the normal direction of the chip 200 (e.g., the Z direction in the figure); the aforementioned thickness T204 refers to the maximum thickness of the insulating layer 204 in the normal direction of the chip 200 (e.g., the Z direction in the figure). In accordance with some embodiments, the thermal expansion coefficient of the insulating layer 204 is greater than the thermal expansion coefficient of the passivation layer 202.

In accordance with some embodiments, the material of the passivation layer 202 may include an inorganic material, an organic material, or a combination thereof, but it is not limited thereto. For example, the inorganic material may include silicon nitride, silicon oxide, silicon oxynitride, another suitable material, or a combination thereof, but it is not limited thereto. For example, the organic material may include polyethylene terephthalate (PET), polyethylene (PE), polyethersulfone (PES), polycarbonate (PC), polymethylmethacrylate (PMMA), polyimide (PI), photosensitive polyimide (PSPI), another suitable passivation material or a combination thereof, but it is not limited thereto.

In accordance with some embodiments, the insulating layer 204 may include a polymer insulating material, for example, may include ABF build-up film (Ajinomoto build-up film), polybenzoxazole (PBO), polyimide, photosensitive polyimide, benzocyclobutene (BCB), another suitable insulating material or a combination thereof, but it is not limited thereto.

As shown in FIG. 1, the encapsulating layer 300 surrounds the electronic component 200U. Specifically, “the encapsulating layer 300 surrounds the electronic component 200U” means that the encapsulating layer 300 is in contact with at least two side surfaces of the electronic component 200U in a cross-sectional view. In accordance with some embodiments, the encapsulating layer 300 is in contact with the side surfaces and the top surface of the electronic component 200U. In accordance with some embodiments, the encapsulating layer 300 is also in contact with part of the circuit structure 400R, for example, with the patterned conductive layer 400-1 and the insulating layer 402-1, but it is not limited thereto.

The encapsulating layer 300 can reduce the influence of water and oxygen in the external environment on the electronic component 200U (especially the chip 200), but it is not limited thereto. In accordance with some embodiments, the encapsulating layer 300 may include molding compound, epoxy, another suitable encapsulating material, or a combination thereof, but it is not limited thereto. In accordance with some embodiments, the encapsulating layer 300 may include filling particles. The filling particles enable the encapsulating layer 300 to have excellent rigidity, reduce scratches on the electronic device, or further reduce the impact of water and oxygen on the electronic component 200U from the external environment, but it is not limited thereto. In accordance with some embodiments, the filling particle of the encapsulating layer 300 may include silicon oxide, aluminum oxide, titanium oxide, another suitable material, or a combination thereof, but it is not limited thereto. Moreover, the particle size of the filling particles may be between 0.1 μm and 50 μm.

As shown in FIG. 1, the circuit structure 400R is adjacent to the electronic component 200U and the encapsulating layer 300, and the circuit structure 400R is electrically connected to the electronic component 200U. In accordance with some embodiments, the circuit structure 400R can serve as a redistribution layer (RDL), so that the circuits of the electronic device can be redistributed and/or the circuits fan-out area can be further increased, or different electronic components can be electrically connected to each other through the circuit structure 400R. For example, the distance between two adjacent contact pads of the circuit structure 400R that contacts one end of the chip 200 may be less than or equal to the distance between two adjacent contact pads of the circuit structure 400R that is far away from one end of the chip 200. Therefore, the circuit structure 400R can adjust the circuit fan-out conditions, but it is not limited thereto. Furthermore, the circuit structure 400R can be applied to wafer level chip scale package (WLCSP), wafer level package (WLP), panel level package (PLP) or other packaging methods, but it is not limited thereto.

The circuit structure 400R serving as a redistribution structure may have one or more insulating layers and patterned conductive layers. For example, as shown in FIG. 1, in accordance with some embodiments, the circuit structure 400R includes an insulating layer 402-1, an insulating layer 402-2, a patterned conductive layer 400-1, a patterned conductive layer 400-2, and a patterned conductive layer 400-3 (serving as a connection part CP). Moreover, the insulating layer 402-1, the insulating layer 402-2, the patterned conductive layer 400-1, the patterned conductive layer 400-2, and the patterned conductive layer 400-3 of the circuit structure 400R may be disposed between the electronic component 200U and the bonding element 420.

In detail, in accordance with some embodiments, the patterned conductive layer 400-1 is disposed in the through hole 202v of the passivation layer 202 and the through hole 204v of the insulating layer 204 to be electrically connected to the chip 200, and a portion of the patterned conductive layer 400-1 is disposed on the surfaces of the electronic component 200U and the encapsulating layer 300.

In accordance with some embodiments, the insulating layer 402-1 covers the patterned conductive layer 400-1 and the encapsulating layer 300, the insulating layer 402-1 has a through hole 402v, and the through hole 402v overlaps with the through holes 202v of the passivation layer 202 and/or the through hole 204v of the insulating layer 204. Specifically, in accordance with some embodiments, in the normal direction of the chip 200 (e.g., the Z direction in the figure), the through hole 402v of the insulating layer 402-1 at least partially overlaps with the through hole 202v of the passivation layer 202 and/or the via hole 204v of the insulating layer 204. However, in accordance with some other embodiments, in the normal direction of the chip 200 (e.g., the Z direction in the figure), the through hole 402v of the insulating layer 402-1 may not overlap with the through hole 202v of the passivation layer 202 and/or the through hole 204v of the insulating layer 204, or the through hole 402v of the insulating layer 402-1 and the through hole 202v of the passivation layer 202 and/or the through hole 204v of the insulating layer 204 may be staggered. In accordance with the embodiments of the present disclosure, “component A overlaps with component B” means that the projections of component A and component B on the same plane at least partially overlap in the Z direction. Furthermore, the insulating layer 402-1 may have a single-layer or multi-layer structure. The insulating layer 402-1 has a thickness T402-1. In accordance with some embodiments, the thickness T402-1 may be between 3 μm and 25 μm (3 μm≤the thickness T402-1≤25 μm), or between 5 μm and 15 μm, for example, 7 μm, 10 μm or 12 μm, but it is not limited thereto. In accordance with some embodiments, the thermal expansion coefficient of the insulating layer 402-1 may be between 10 ppm/K and 50 ppm/K (10 ppm/K≤the thermal expansion coefficient of the insulating layer 402-1≤50 ppm/K), or between 15 ppm/K to 45 ppm/K, for example, 16 ppm/K, 22 ppm/K or 35 ppm/K, but it is not limited thereto.

In accordance with some embodiments, the patterned conductive layer 400-2 is disposed in the through hole 402v of the insulating layer 402-1 to be electrically connected to the patterned conductive layer 400-1, and a portion of the patterned conductive layer 400-2 is disposed on the surface of the insulating layer 402-1. In accordance with some embodiments, the patterned conductive layer 400-2 at least partially overlaps with the patterned conductive layer 400-1 in the normal direction of the chip 200 (e.g., the Z direction in the figure).

The patterned conductive layer 400-3 can serve as the connection part CP, as the portion connecting the circuit structure 400R and the bonding element 420. In accordance with some embodiments, the patterned conductive layer 400-3 is, for example, an under-bump metallization (UBM) layer. In accordance with some embodiments, the connection part CP is disposed on the surface of the patterned conductive layer 400-2, and the connection part CP is disposed between the patterned conductive layer 400-2 and the bonding element 420. In accordance with some embodiments, in the normal direction of the chip 200 (e.g., the Z direction in the figure), the connection part CP at least partially overlaps with the patterned conductive layer 400-2 and the patterned conductive layer 400-1. Furthermore, in accordance with some embodiments, the connection part CP has a width Wcp, the patterned conductive layer 400-2 has a width W400-2, and the width Wcp of the connection part CP is greater than or equal to 0.3 times the width W400-2 of the patterned conductive layer 400-2 and is less than or equal to 1.5 times the width W400-2 of the patterned conductive layer 400-2 (that is, 0.3×the width W400-2≤the width Wcp≤1.5×the width W400-2). In accordance with some embodiments, the width Wcp is greater than or equal to 0.5 times the width W400-2 and less than or equal to 1.2 times the width W400-2, but it is not limited thereto.

It should be noted that when the widths of the connection part CP and the patterned conductive layer 400-2 comply with the aforementioned configuration, it can alleviate problems such as excessive concentration of stress on the joint surface during bonding, which may cause peeling or breakage between the bonding element 420 and the connection part CP. Therefore, the structural strength or reliability of the electronic device can be improved. Furthermore, the aforementioned width Wcp refers to the maximum width of the connection part CP in the direction perpendicular to the normal direction of the chip 200 (for example, the X direction in the figure); and the aforementioned width W400-2 refers to the maximum width of the patterned conductive layer 400-2 in the direction perpendicular to the normal direction of the chip 200 (for example, the X direction in the figure).

In accordance with some embodiments, the insulating layer 402-2 covers the patterned conductive layer 400-2 and the insulating layer 402-1, and the connection part CP is disposed in the insulating layer 402-2. Furthermore, the insulating layer 402-2 may have a single-layer or multi-layer structure. The insulating layer 402-2 may be the same as or different from the insulating layer 402-1. For example, in accordance with some embodiments, the thickness of the insulating layer 402-2 is greater than the thickness of the insulating layer 402-1. Alternatively, in accordance with some embodiments, the thermal expansion coefficient of the insulating layer 402-2 is smaller than the thermal expansion coefficient of the insulating layer 402-1, but it is not limited thereto.

In accordance with some embodiments, the patterned conductive layer 400-1, the patterned conductive layer 400-2 and the patterned conductive layer 400-3 may include a conductive material, such as copper (Cu), titanium (Ti), aluminum (Al), tantalum (Ta), silver (Ag), gold (Au), tin (Sn), molybdenum (Mo), chromium (Cr), nickel (Ni), platinum (Pt), alloys of the aforementioned metals, another suitable conductive material or a combination thereof, but it is not limited thereto. Furthermore, the materials of the patterned conductive layer 400-1, the patterned conductive layer 400-2 and the patterned conductive layer 400-3 may be the same or different from each other.

In accordance with some embodiments, the material of the insulating layer 402-1 may include a polymer insulating material, such as polybenzoxazole (PBO), polyimide, benzocyclobutene (BCB), resin, polymer, another suitable polymer insulating material or a combination thereof, but it is not limited thereto. In accordance with some other embodiments, the insulating layer 402-1 may include silicon nitride, silicon oxide, silicon oxynitride, phosphosilicate glass (PSG), borosilicate glass (BSG), boron-doped phosphosilicate glass (BPSG), another suitable insulating material, or a combination thereof, but it is not limited thereto.

In accordance with some embodiments, the insulating layer 402-2 may include an insulating material, such as solder mask, epoxy resin, an inorganic material (e.g., silicon oxide, silicon nitride, silicon oxynitride, metal oxide, or a combination thereof), an organic polymer material (e.g., polyimide resin, benzocyclobutene, parylene, naphthalene polymer, fluorocarbon, or acrylic ester), another suitable insulating material or a combination thereof, but it is not limited thereto. In accordance with some embodiments, the insulating layer 402-2 may be formed of a solder resist material, but it is not limited thereto.

It should be understood that according to different embodiments, the circuit structure 400R may include any suitable number of insulating layers and patterned conductive layers, and the present disclosure is not limited to the aspects illustrated in the embodiments.

As shown in FIG. 1, the bonding element 420 overlaps with the connection part CP and is electrically connected to the electronic component 200U. Specifically, the bonding element 420 is electrically connected to the chip 200 of the electronic component 200U through the connection part CP, the patterned conductive layer 400-2 and the patterned conductive layer 400-1 of the circuit structure 400R. In accordance with some embodiments, the bonding element 420 is disposed on the surface of the connection part CP and in contact with the connection part CP. In accordance with some embodiments, one end of the bonding element 420 is electrically connected to the connection part CP, and the other end is electrically connected to a printed circuit board (PCB) (not illustrated) or other external components, but the present disclosure is not limited thereto. In accordance with some embodiments, the bonding element 420 reacts with the connection part CP to form an intermediate layer (not illustrated), and at least a portion of the intermediate layer is disposed between the connection part CP and the bonding element 420.

In accordance with some embodiments, the material of the bonding element 420 may include tin, silver, lead-free tin, copper, nickel, gold, gallium, another suitable material or a combination thereof, but it is not limited thereto.

As shown in FIG. 1, the auxiliary pad 410 is disposed in the circuit structure 400R. In other words, the auxiliary pad 410 is in the same layer as at least one insulating layer in the circuit structure 400R, and the auxiliary pad 410 is surrounded by at least one insulating layer in the circuit structure 400R. Specifically, the auxiliary pad 410 is disposed between the connection part CP and the chip 200, and the connection part CP is disposed between the auxiliary pad 410 and the bonding element 420. In the normal direction of the chip 200 (for example, the Z direction in the figure), the connection part CP overlaps with the auxiliary pad 410. For example, in the Z direction, the geometric center of the auxiliary pad 410 overlaps with the connection part CP. Alternatively, in a cross-sectional diagram, an intersection O1 of the diagonal lines of the auxiliary pad 410 overlaps with the connection part CP (as shown in FIG. 1). In accordance with some embodiments, the auxiliary pad 410 is in contact with the insulating layer 402-1, but it is not limited thereto. In accordance with some embodiments, the auxiliary pad 410 is in contact with the patterned conductive layer 400-1 and/or the patterned conductive layer 400-2, but it is not limited thereto. In accordance with some embodiments, the auxiliary pad 410 is disposed adjacent to the through hole 402v and in contact with the patterned conductive layer 400-2 in the through hole 402v, but it is not limited thereto.

It should be noted that when the connection part CP is disposed between the auxiliary pad 410 and the bonding element 420, and the connection part CP overlaps with the auxiliary pad 410, the auxiliary pad 410 can improve the stress balance of the electronic device and reduce the stress in the vertical direction when the bonding element 420 is joined with the connection part CP. The risk of the bonding element 420 or the connection part CP being broken or peeling off from each other can be reduced, thus improving the reliability of the electronic device.

In accordance with some embodiments, the thermal expansion coefficient of the auxiliary pad 410 is smaller than the thermal expansion coefficient of the insulating layer of the circuit structure 400R (the insulating layer 402-1 and/or the insulating layer 402-2). Specifically, in accordance with some embodiments, the thermal expansion coefficient of the auxiliary pad 410 may be between 0.1 ppm/K and 12 ppm/K (0.1 ppm/K≤the thermal expansion coefficient of the auxiliary pad 410≤12 ppm/K), or between 1 ppm/K and 11 ppm/K, for example, 2 ppm/K, 3 ppm/K, 4 ppm/K, 5 ppm/K, 6 ppm/K, 7 ppm/K, 8 ppm/K, 9 ppm/K or 10 ppm/K, but it is not limited thereto.

In accordance with some embodiments, the Young's modulus of the auxiliary pad 410 is greater than the Young's modulus of the insulating layer of the circuit structure 400R (the insulating layer 402-1 and/or the insulating layer 402-2). Specifically, in accordance with some embodiments, the Young's modulus of the auxiliary pad 410 may be between 220 GPa and 270 GPa (220 GPa≤Young's modulus of the auxiliary pad 410≤270 GPa), for example, 230 GPa, 240 GPa, 250 GPa, or 260 GPa, but it is not limited thereto. The Young's modulus referred to in the present disclosure can be obtained by measuring the stress and strain curves of the sample with a universal testing machine. For example, it can be measured with reference to ASTM-D638, ASTM-D882, ASTM-D3039 or another suitable standard method, but it not limited thereto.

It should be noted that when the Young's modulus of the auxiliary pad 410 is greater than the Young's modulus of the insulating layer of the circuit structure 400R, the stress transfer between the bonding element 420 and the circuit structure 400R can be reduced or the stress is not transferred, or the vertical stress can be supported or reduced. Therefore, the reliability of the electronic device can be improved.

In addition, in accordance with some embodiments, the intrinsic stress of the auxiliary pad 410 may be between +800 MPa and −1000 MPa (−1000 MPa≤the intrinsic stress of the auxiliary pad 410≤+800 MPa), or between +600 MPa and −800 MPa, or between +400 MPa and −600 MPa, for example, +300 MPa, +200 MPa, +100 MPa, 0 MPa, −100 MPa, −200 MPa, −300 MPa, −400 MPa or −500 MPa, but it is not limited thereto.

It should be noted that when the auxiliary pad 410 has the aforementioned specific intrinsic stress, it can compensate the mechanical characteristics of the circuit structure 400R and improve the stress balance, thereby improving the reliability of the electronic device. Furthermore, in accordance with some embodiments, a spectral reflection ellipsometer can be used to measure the thickness and refractive index of the auxiliary pad 410, and the intrinsic stress of the auxiliary pad 410 can be determined based on the difference in refractive index.

In addition, as shown in FIG. 1, the auxiliary pad 410 has a width W410. In accordance with some embodiments, the width W410 of the auxiliary pad 410 is smaller than the width W400-2 of the patterned conductive layer 400-2. In other words, the width W410 of the auxiliary pad 410 is smaller than the width of the patterned conductive layer in contact with the connection part CP. In accordance with some embodiments, the width W410 of the auxiliary pad 410 is greater than or equal to 0.3 times the width W400-2 of the patterned conductive layer 400-2, and is less than or equal to 0.6 times the width W400-2 of the patterned conductive layer 400-2 (that is, 0.3×the width W400-2≤the width W410≤0.6×the width W400-2). In accordance with some embodiments, the width W410 is greater than or equal to 0.4 times the width W400-2 and less than or equal to 0.5 times the width W400-2, but it is not limited thereto.

It should be noted that when the widths of the auxiliary pad 410 and the patterned conductive layer 400-2 comply with the aforementioned configuration, it can alleviate problems such as excessive concentration of stress on the joint surface during bonding, which may cause peeling or breakage between the bonding element 420 and the connection part CP. Therefore, the structural strength or reliability of the electronic device can be improved. Furthermore, the aforementioned width W410 refers to the maximum width of the auxiliary pad 410 in the direction perpendicular to the normal direction of the chip 200 (for example, the X direction in the figure); and the definition of the width W400-2 is as described above, which will not be repeated here.

In addition, the auxiliary pad 410 has a thickness T410. In accordance with some embodiments, the ratio of the thickness T410 of the auxiliary pad 410 to the thickness (the thickness T402-1 or the thickness T402-2) of the insulating layer of the circuit structure 400R (the insulating layer 402-1 or the insulating layer 402-2) may be between 0.5 and 1 (that is, 0.5≤the thickness T410/the thickness T402-1≤1, 0.5≤the thickness T410/the thickness T402-2≤1), for example, the ratio may be 0.6, 0.7, 0.8 or 0.9, but it is not limited thereto. Specifically, in accordance with some embodiments, the thickness T410 of the auxiliary pad 410 may be between 1 μm and 30 μm (1 μm≤the thickness T410≤30 μm), or between 5 μm and 25 μm, such as 10 μm, 15 μm or 20 μm, but it is not limited thereto.

It should be noted that when the thickness T410 of the auxiliary pad 410 and the thickness of the insulating layer of the circuit structure 400R comply with the aforementioned configuration, it can alleviate problems such as excessive concentration of stress on the joint surface during bonding, which may cause peeling or breakage between the bonding element 420 and the connection part CP. Therefore, the structural strength or reliability of the electronic device can be improved. Furthermore, the aforementioned thickness T410 refers to the maximum thickness of the auxiliary pad 410 in the normal direction of the chip 200 (e.g., the Z direction in the figure); and the definition of the thickness T402-1 or the thickness T402-2 is as described above, which will not be repeated here.

In accordance with some embodiments, the material of the auxiliary pad 410 may include silicon oxide (SiOx), silicon nitride (SiNx), titanium dioxide (TiO₂), another suitable material, or a combination thereof, but it is not limited thereto. It should be understood that the material of the auxiliary pad 410 is not limited to the foregoing. In accordance with some other embodiments, materials with the aforementioned specific thermal expansion coefficient, Young's modulus or intrinsic stress properties can also be used to form the auxiliary pad 410.

In addition, as shown in FIG. 1, in accordance with some embodiments, part of the side surfaces of the auxiliary pad 410 may be aligned or co-planar with the side surface of the patterned conductive layer 400-1, but the present disclosure is not limited thereto. In accordance with some other embodiments, part of the side surfaces of the auxiliary pad 410 may protrude from the side surface of the patterned conductive layer 400-1, or part of the side surfaces of the patterned conductive layer 400-1 may protrude from the side surface of the auxiliary pad 410, but it is not limited thereto. Furthermore, in accordance with some embodiments, the auxiliary pad 410 may have an inclined side surface, for example, the auxiliary pad 410 may have a trapezoidal shape, but it is not limited thereto. According to different embodiments, the auxiliary pad 410 can have any suitable shape, such as rectangular, triangular or irregular shape, but it is not limited thereto. In accordance with some embodiments, the auxiliary pad 410 may have a curved top corner or a curved bottom corner.

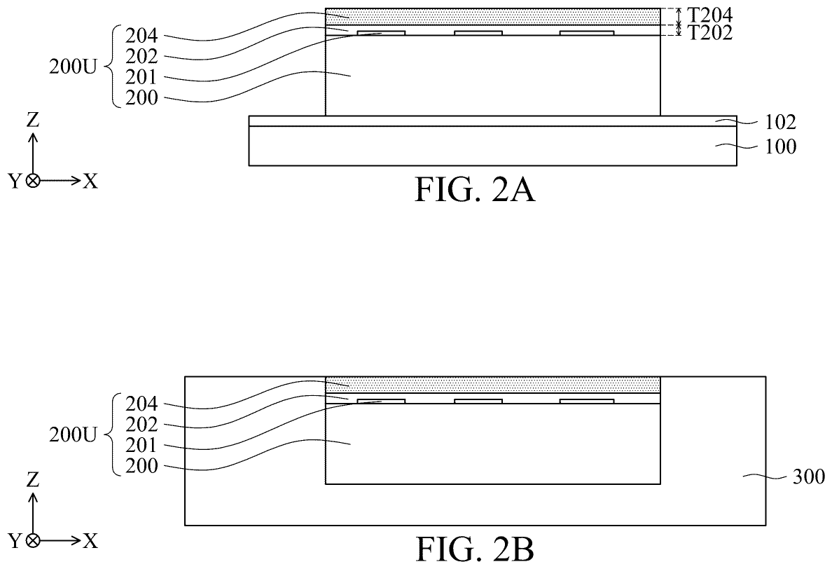

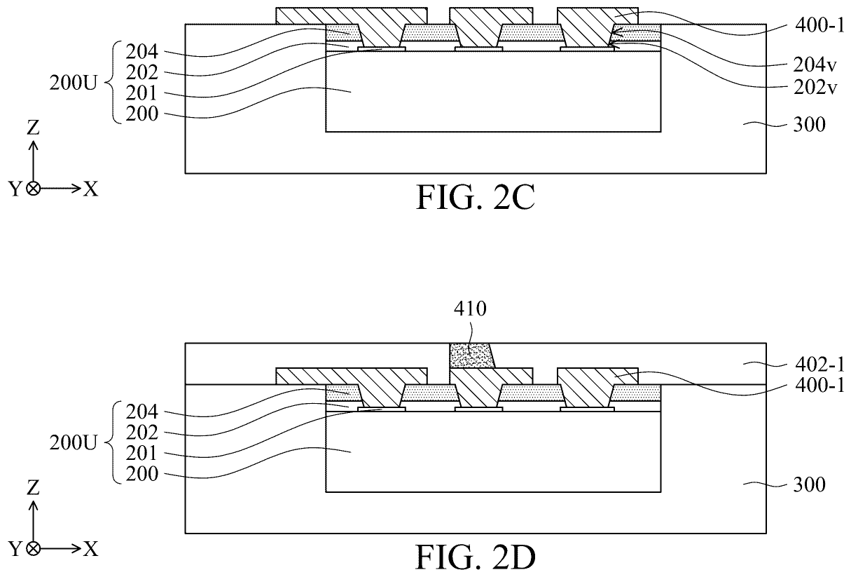

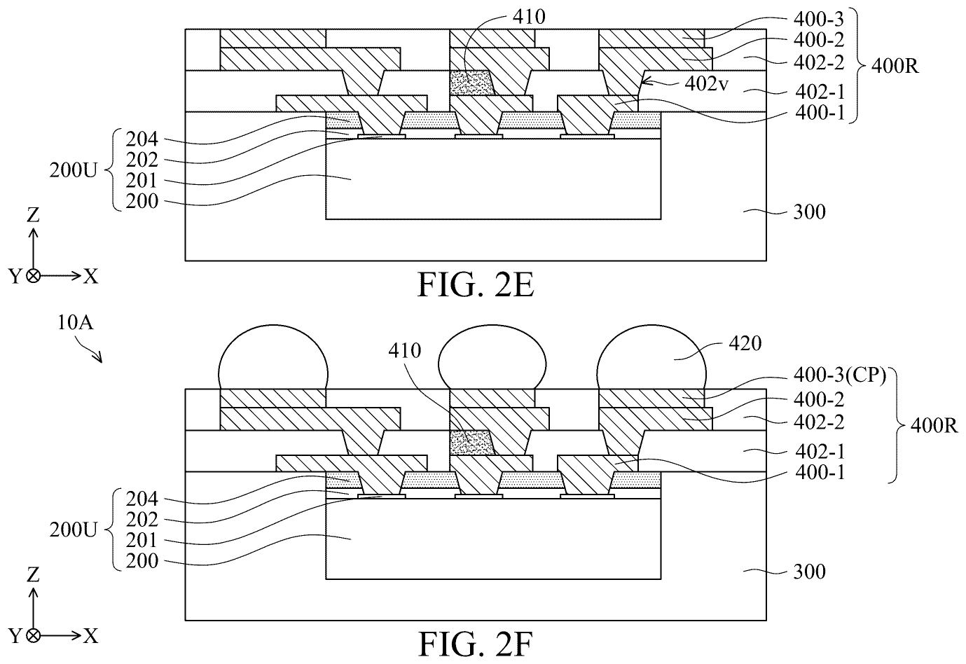

Next, please refer to FIGS. 2A to 2F, which are cross-sectional diagrams of an electronic device during the intermediate stages of the manufacturing process in accordance with some embodiments of the present disclosure. The following descriptions use the electronic device 10A as an example to further illustrate the method of manufacturing the electronic device in accordance with some embodiments of the present disclosure with reference to FIGS. 2A to 2F.

It should be understood that, in accordance with some embodiments, additional operating steps may be provided before, during and/or after the method of manufacturing the electronic device 10A. In accordance with some embodiments, some of the described operating steps may be replaced or omitted. In accordance with some embodiments, the order of some of the operational steps is interchangeable. In addition, it should be understood that components or elements that are identical or similar to those mentioned above will be denoted by the same or similar numerals, and their materials, manufacturing methods and functions are the same or similar to those described above, and thus will not be repeated in the following description.

First, referring to FIG. 2A, a substrate 100 is provided. The substrate 100 may be a carrier substrate. In accordance with some embodiments, the substrate 100 may include a glass carrier substrate, a ceramic carrier substrate, or another suitable carrier substrate, but it is not limited thereto. In accordance with some embodiments, the substrate 100 is a chip or a wafer, but it is not limited thereto.

A release layer 102 may be formed on the substrate 100. The release layer 102 may be removed together with the substrate 100 from a subsequently formed overlying structure (e.g., electronic component 200U). The release layer 102 may include a polymer-based material, but it is not limited thereto. In accordance with some embodiments, the release layer 102 may include a thermal insulating material based on epoxy resin, which loses its adhesion when heated, such as thermal release tape (HRT), light-to-heat conversion tape (LTHC), or stripping coating. In accordance with some other embodiments, the release layer 102 may include ultra-violet (UV) glue that loses adhesion when exposed to ultraviolet light. In accordance with some embodiments, the release layer 102 may lose its adhesion through a laser peeling process. In accordance with some embodiments, the release layer 102 may be formed through a coating and curing process, a lamination process, another suitable process, or a combination thereof. In accordance with some embodiments, the step of forming the release layer 102 may be omitted. In other words, a subsequent layer can be formed directly on the substrate 100.

Next, the electronic component 200U may be formed on the substrate 100, and the electronic component 200U may be located on the release layer 102. In accordance with some embodiments, the chip 200, the conductive pad 201, the passivation layer 202 and the insulating layer 204 are sequentially formed on the substrate 100. Specifically, in accordance with some embodiments, a wafer (not illustrated) may be placed on the substrate 100 and the release layer 102 first, with a passivation layer 202 on the wafer, and the insulating layer 204 may be formed on the wafer and the release layer 102. Next, a cutting process may be performed to cut the wafer into chips 200. In accordance with some embodiments, the cut chip 200 and the passivation layer 202 and the insulating layer 204 thereon may be further transferred to another substrate 100 and the release layer 102 for subsequent processes.

In accordance with some embodiments, the polymer insulating material may be formed on the substrate 100 and the release layer 102 through a coating process, a printing process, a chemical vapor deposition process, another suitable method, or a combination thereof to obtain the insulating layer 204.

In accordance with some embodiments, the cutting process may include a laser cutting process, but it is not limited thereto. Furthermore, as mentioned above, the thickness T204 of the insulating layer 204 may b greater than the thickness T202 of the passivation layer 202. With this configuration, the insulating layer 204 can provide a buffering effect and reduce the risk of cracking of the electronic component 200U caused by the cutting process.

Referring to FIG. 2B, an encapsulating layer 300 may be formed to surround the electronic component 200U. Specifically, in accordance with some embodiments, the electronic component 200U may be first transferred and placed upside down on another carrier substrate, and then the encapsulating layer 300 may be formed on the carrier substrate. Afterwards, the carrier substrate may be removed, for example, through a laser lift-off process to obtain the structure shown in FIG. 2B.

In accordance with some embodiments, the molding compound, epoxy resin, another suitable encapsulating material or a combination thereof may be formed around the electronic component 200U by a compression molding process, a transfer molding process or another suitable method to obtain the encapsulating layer 300. In accordance with some embodiments, the material of the encapsulating layer 300 may be in a liquid or semi-liquid form during the molding process and then solidified.

Referring to FIG. 2C, portions of the passivation layer 202 and the insulating layer 204 may be removed to form a through hole 202v and a through hole 204v. The through hole 202v may expose a portion of the conductive pad 201. In accordance with some embodiments, the passivation layer 202 and the insulating layer 204 may be patterned through one or more photolithography processes and/or etching processes to form the through hole 202v and the through hole 204v. In accordance with some embodiments, the photolithography process may include photoresist coating (e.g., spin coating), soft baking, hard baking, mask alignment, exposure, post-exposure baking, photoresist development, cleaning and drying, etc., but it is not limited thereto. The etching process may include a dry etching process or a wet etching process, but it is not limited thereto.

Next, a patterned conductive layer 400-1 may be formed on the electronic component 200U and in the through hole 202v and the through hole 204v. In accordance with some embodiments, the conductive material may be formed on the electronic component 200U and in the through hole 202v and the through hole 204v through a physical vapor deposition process, an electroplating process, an electroless plating process, another suitable method, or a combination thereof. Furthermore, the conductive material may be patterned through one or more photolithography processes and/or etching processes to form the patterned conductive layer 400-1.

Referring to FIG. 2D, the auxiliary pad 410 may be formed on the patterned conductive layer 400-1. In accordance with some embodiments, the auxiliary pad 410 may be in contact with the patterned conductive layer 400-1. In accordance with some embodiments, the material of the auxiliary pad 410 may be formed on the patterned conductive layer 400-1 through a coating process, a printing process, a lamination process, a chemical vapor deposition process, another suitable method, or a combination thereof.

Next, an insulating layer 402-1 may be formed on the patterned conductive layer 400-1 and the encapsulating layer 300. In accordance with some embodiments, the insulating layer 402-1 may also cover the auxiliary pad 410, and then a planarization process may be performed to make the top surface of the insulating layer 402-1 and the top surface of the auxiliary pad 410 substantially aligned, so as to obtain the structure shown in FIG. 2D. In accordance with some embodiments, the insulating material may be formed on the patterned conductive layer 400-1 and the encapsulating layer 300 through a coating process, a printing process, a chemical vapor deposition process, another suitable method, or a combination thereof to obtain the insulating layer 402-1.

Referring to FIG. 2E, a portion of the insulating layer 402-1 may be removed to form a through hole 402v. In accordance with some embodiments, the insulating layer 402-1 may be patterned through one or more photolithography processes and/or etching processes to form the through hole 402v.

Next, a patterned conductive layer 400-2 may be formed on the insulating layer 402-1 and in the through hole 402v. In accordance with some embodiments, the patterned conductive layer 400-2 may be in contact with the auxiliary pad 410. In accordance with some embodiments, the conductive material may be formed on the insulating layer 402-1 and in the through hole 402v through a physical vapor deposition process, an electroplating process, an electroless plating process, another suitable method, or a combination thereof. Furthermore, the conductive material may be patterned through one or more photolithography processes and/or etching processes to form the patterned conductive layer 400-2.

Next, a patterned conductive layer 400-3 (connection part CP) may be formed on the patterned conductive layer 400-2, and the patterned conductive layer 400-3 may overlap with the auxiliary pad 410. In accordance with some embodiments, the conductive material can be formed on the patterned conductive layer 400-2 through a physical vapor deposition process, an electroplating process, an electroless plating process, another suitable method, or a combination thereof. Furthermore, the conductive material may be patterned through one or more photolithography processes and/or etching processes to form the patterned conductive layer 400-3.

Next, an insulating layer 402-2 may be formed on the patterned conductive layer 400-2 and the insulating layer 402-1. In accordance with some embodiments, the insulating layer 402-2 may also cover the patterned conductive layer 400-3, and then a planarization process can be performed to make the top surface of the insulating layer 402-2 and the top surface of the patterned conductive layer 400-3 substantially aligned to obtain the structure shown in FIG. 2E. In accordance with some embodiments, the insulating material may be formed on the patterned conductive layer 400-2 and the insulating layer 402-1 through a coating process, a printing process, a chemical vapor deposition process, another suitable method, or a combination thereof, to obtain the insulating layer 402-2.

Referring to FIG. 2F, a bonding element 420 may be formed on the patterned conductive layer 400-3 (connection part CP). The bonding element 420 may be disposed corresponding to the connection part CP. That is, in the normal direction of the chip 200 (the Z direction in the figure), the bonding element 420 may overlap with the connection part CP. In accordance with some embodiments, the bonding element 420 may be joined to the connection part CP through a reflow process, a fusion joining process, a hybrid joining process, a metal-to-metal joining process, another suitable method, or a combination thereof. At this stage, the manufacture of the electronic device 10A is substantially completed. By turning the electronic device 10A upside down, the structure shown in FIG. 1 is obtained.

According to the foregoing, in the embodiments of the method of manufacturing the electronic device 10A, a chip first process is adopted, but the present disclosure is not limited thereto. In accordance with some other embodiments, the method of manufacturing the electronic device may also adopt a chip last/RDL first process. That is, the circuit structure 400R may be formed first.

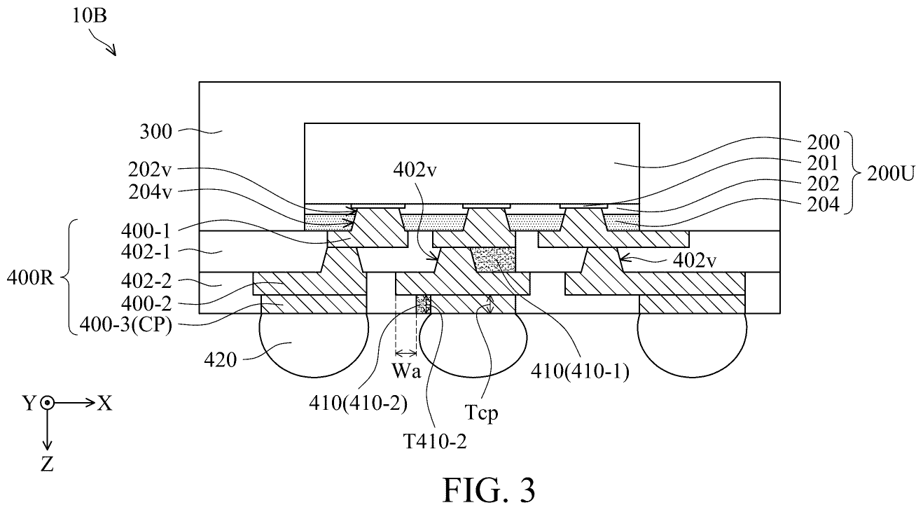

Please refer to FIG. 3, which is a cross-sectional diagram of an electronic device 10B in accordance with some other embodiments of the present disclosure. It should be understood that, for clarity of explanation, some components of the electronic device 10B may be omitted in the drawings, and only some components are schematically illustrated. In accordance with some embodiments, additional features may be added to the electronic device 10B described below. In accordance with some other embodiments, some features of the electronic device 10B described below may be replaced or omitted.

The electronic device 10B is substantially similar to the aforementioned electronic device 10A. Compared with the electronic device 10A, the electronic device 10B includes a plurality of auxiliary pads 410. Specifically, the electronic device 10B may include an auxiliary pad 410-1 and an auxiliary pad 410-2 adjacent to at least one side of the connection part CP. The auxiliary pad 410-2 is also disposed in the circuit structure 400R, and the auxiliary pad 410-2 is disposed between the bonding element 420 and the patterned conductive layer 400-2, and the auxiliary pad 410-2 is in contact with the connection part CP. In the normal direction of the chip 200 (e.g., the Z direction in the figure), the auxiliary pad 410-2 overlaps with the patterned conductive layer 400-2.

The thermal expansion coefficient of the auxiliary pad 410-2 is smaller than the thermal expansion coefficient of the insulating layer of the circuit structure 400R (the insulating layer 402-1 and/or the insulating layer 402-2). Specifically, in accordance with some embodiments, the thermal expansion coefficient of the auxiliary pad 410-2 may be between 0.1 ppm/K and 12 ppm/K (0.1 ppm/K≤the thermal expansion coefficient of the auxiliary pad 410-2≤12 ppm/K), or between 1 ppm/K and 11 ppm/K, for example, 2 ppm/K, 3 ppm/K, 4 ppm/K, 5 ppm/K, 6 ppm/K, 7 ppm/K, 8 ppm/K, 9 ppm/K or 10 ppm/K, but it is not limited thereto.

In accordance with some embodiments, the Young's modulus of the auxiliary pad 410-2 is greater than the Young's modulus of the insulating layer of the circuit structure 400R (the insulating layer 402-1 and/or the insulating layer 402-2). Specifically, in accordance with some embodiments, the Young's modulus of the auxiliary pad 410-2 may be between 220 GPa and 270 GPa (220 GPa≤Young's modulus of the auxiliary pad 410-2≤270 GPa), for example, 230 GPa, 240 GPa, 250 GPa, or 260 GPa, but it is not limited thereto.

In accordance with some embodiments, the intrinsic stress of the auxiliary pad 410-2 may be between −100 MPa and −1000 MPa (−1000 MPa≤the intrinsic stress of the auxiliary pad 410-2≤−100 MPa), for example, −200 MPa, −300 MPa, −400 MPa, −500 MPa, −600 MPa, −700 MPa, −800 MPa or −900 MPa, but it is not limited thereto.

It should be noted that when the auxiliary pad 410-2 has the aforementioned specific intrinsic stress, it can further compensate for the mechanical characteristics of the circuit structure 400R and improve the stress balance, thereby improving the reliability of the electronic device.

Furthermore, the auxiliary pad 410-2 has a thickness T410-2, the connection part CP has a thickness Tcp. The ratio of the thickness T410-2 of the auxiliary pad 410-2 to the thickness Tcp of the connection part CP may be between 0.8 and 1. (that is, 0.8≤the thickness T410-2/the thickness Tcp≤1), for example, the ratio may be 0.85, 0.9 or 0.95, but it is not limited thereto. Specifically, in accordance with some embodiments, the thickness T410-2 of the auxiliary pad 410-2 may be between 1 μm and 30 μm (1 μm≤the thickness T410-2≤30 μm), or between 5 μm and 25 μm, for example, 10 μm, 15 μm or 20 μm, but it is not limited thereto. Furthermore, the thickness T410-2 of the auxiliary pad 410-2 may be the same as or different from the thickness T410-1 of the auxiliary pad 410-1. In accordance with some embodiments, the thickness T410-2 of the auxiliary pad 410-2 is smaller than the thickness T410-1 of the auxiliary pad 410-1, thereby reducing the vertical stress during bonding of the connection structures. Therefore, the packaging reliability of the electronic device can be improved.

It should be noted that when the thickness T410-2 of the auxiliary pad 410-2 and the thickness Top of the connection part CP comply with the aforementioned configuration, it can alleviate problems such as excessive concentration of stress on the joint surface during bonding, which may cause peeling or breakage between the bonding element 420 and the connection part CP. Therefore, the structural strength or reliability of the electronic device can be improved.

In addition, as shown in FIG. 3, the side surface of the auxiliary pad 410-2 is not aligned with the side surface of the patterned conductive layer 400-2, and the side surface of the patterned conductive layer 400-2 may protrude from the side surface of the auxiliary pad 410-2. Specifically, there is a distance Wa between the side surface of the auxiliary pad 410-2 and the side surface of the patterned conductive layer 400-2, and the distance Wa may be between 0.125 μm and 0.2 μm (that is, 0.125 μm≤the distance Wa≤0.2 μm), for example, 0.13 μm, 0.14 μm, 0.15 μm, 0.16 μm, 0.17 μm, 0.18 μm or 0.19 μm, but it is not limited thereto.

It should be noted that when the side surface of the auxiliary pad 410-2 and the side surface of the patterned conductive layer 400-2 comply with the aforementioned configuration, it can alleviate problems such as excessive concentration of stress on the joint surface during bonding, which may cause peeling or breakage between the bonding element 420 and the connection part CP. Therefore, the structural strength or reliability of the electronic device can be improved. Furthermore, the aforementioned distance Wa refers to the minimum distance between the side surface of the auxiliary pad 410-2 and the side surface of patterned conductive layer 400-2 in the direction perpendicular to the normal direction of the chip 200 (e.g., the X direction in the figure).

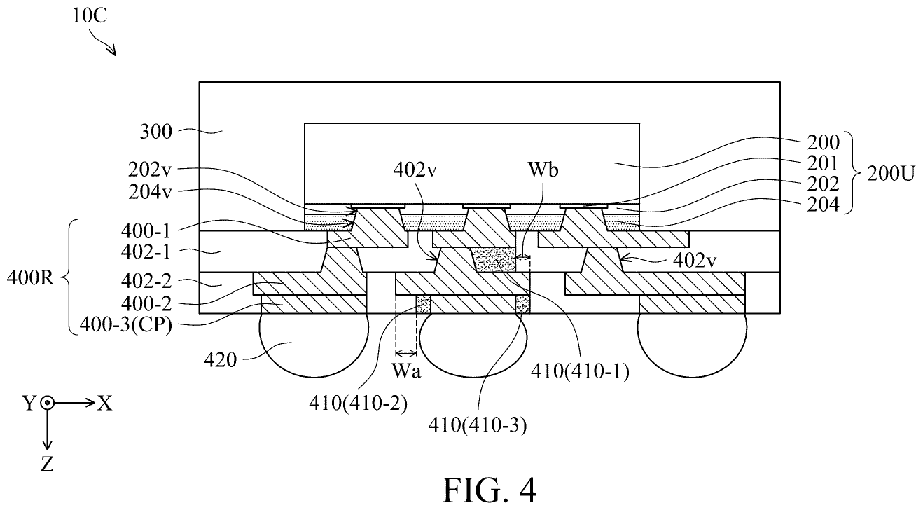

Please refer to FIG. 4, which is a cross-sectional diagram of an electronic device 10C in accordance with some other embodiments of the present disclosure. It should be understood that, for clarity of explanation, some components of the electronic device 10C may be omitted in the drawings, and only some components are schematically illustrated. In accordance with some embodiments, additional features may be added to the electronic device 10C described below. In accordance with some other embodiments, some features of the electronic device 10C described below may be replaced or omitted.

The electronic device 10C is substantially similar to the aforementioned electronic device 10B. Compared with the electronic device 10B, the electronic device 10C further includes an auxiliary pad 410-3. In this embodiment, the auxiliary pad 410-2 is adjacent to one side of the connection part CP, and the auxiliary pad 410-3 is adjacent to the other side of the connection part CP. The auxiliary pad 410-3 is also disposed in the circuit structure 400R, and the auxiliary pad 410-3 is disposed between the bonding element 420 and the patterned conductive layer 400-2, and the auxiliary pad 410-3 is in contact with the connection part CP. In the normal direction of the chip 200 (e.g., the Z direction in the figure), the auxiliary pad 410-3 overlaps with the patterned conductive layer 400-2. The auxiliary pad 410-3 may have a similar or identical thermal expansion coefficient, Young's modulus, intrinsic stress and thickness range as the auxiliary pad 410-2, which will not be repeated here.

As shown in FIG. 4, the side surface of the auxiliary pad 410-3 is aligned with the side surface of the patterned conductive layer 400-2, and the side surface of the auxiliary pad 410-3 protrudes from the side surface of the auxiliary pad 410-1. There is a distance Wb between the side surface of the auxiliary pad 410-3 and the side surface of the auxiliary pad 410-1, and the distance Wb may be between 0.125 μm and 0.2 μm (that is, 0.125 μm≤the distance Wb≤0.2 μm), for example, 0.13 μm, 0.14 μm, 0.15 μm, 0.16 μm, 0.17 μm, 0.18 μm or 0.19 μm, but it is not limited thereto. In accordance with some embodiments, the distance Wa between the side surface of the auxiliary pad 410-2 and the side surface of the patterned conductive layer 400-2 is equal to the distance Wb between the side surface of the auxiliary pad 410-3 and the side surface of the auxiliary pad 410-1.

It should be noted that when the side surfaces of the auxiliary pad 410-1, auxiliary pad 410-2, and auxiliary pad 410-3 and the side surfaces of the patterned conductive layer 400-2 comply with the aforementioned configuration, it can alleviate problems such as excessive concentration of stress on the joint surface during bonding, which may cause peeling or breakage between the bonding element 420 and the connection part CP. Therefore, the structural strength or reliability of the electronic device can be improved. Furthermore, the aforementioned distance Wb refers to the minimum distance between the side surface of the auxiliary pad 410-3 and the side surface of the auxiliary pad 410-1 in the direction perpendicular to the normal direction of the chip 200 (e.g., the X direction in the figure).

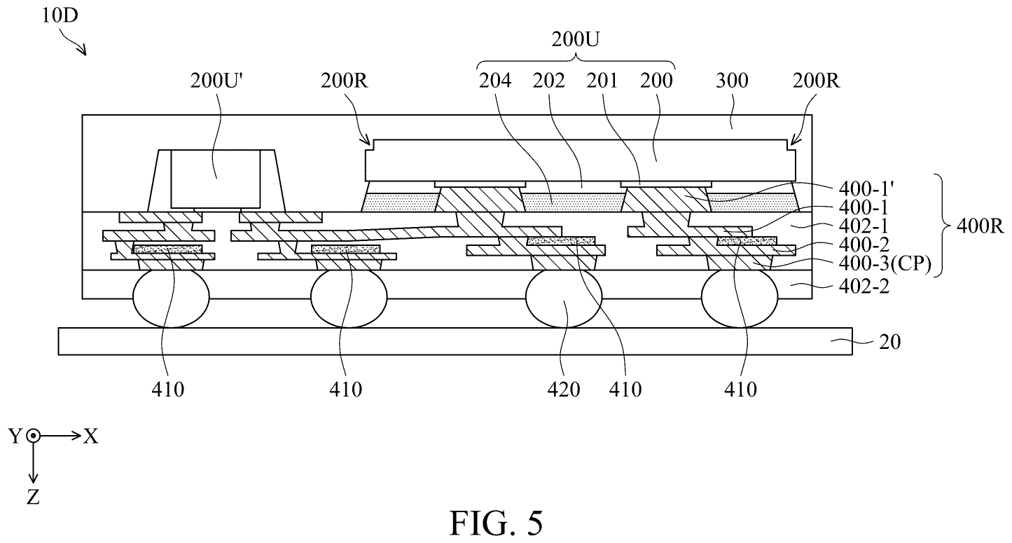

Next, please refer to FIG. 5, which is a cross-sectional diagram of an electronic device 10D in accordance with some other embodiments of the present disclosure. It should be understood that, for clear explanation, some components of the electronic device 10D may be omitted in the drawings, and only some components are schematically illustrated. In accordance with some embodiments, additional features may be added to the electronic device 10D described below. In accordance with some other embodiments, some features of the electronic device 10D described below may be replaced or omitted.

The electronic device 10D further includes an electronic component 200U′, and the electronic component 200U′ is integrated and packaged together with the electronic component 200U in the electronic device 10D. In accordance with some embodiments, the electronic component 400 may include a resistor, a capacitor, an inductor, a transistor or other components, but it is not limited thereto. Furthermore, the circuit structure 400R of the electronic device 10D further includes a patterned conductive layer 400-1′, and the patterned conductive layer 400-1′ is disposed between the chip 200 and the patterned conductive layer 400-1. In addition, the electronic device 10D can be bonded to an external electronic component 20 through the bonding element 420. One end of the bonding element 420 is electrically connected to the connection part CP, and the other end of the bonding element 420 is electrically connected to the external electronic component 20. For example, the external electronic component 20 may include a printed circuit board (PCB), but the present disclosure is not limited thereto.

As shown in FIG. 5, in this embodiment, the chip 200 has an accommodating space 200R, and a portion of the encapsulating layer 300 is disposed in the accommodating space 200R. Specifically, the accommodating space 200R may be a recessed structure, the accommodating space 200R may be located on a side of the chip 200 where the circuit structure 400R is not provided, and the accommodating space 200R may be disposed at a corner of the chip 200. The accommodating space 200R can accommodate the encapsulating layer 300, thereby reducing stress concentration at the corners of the chip 200. Furthermore, the accommodating space 200R can also serve as an alignment mark.

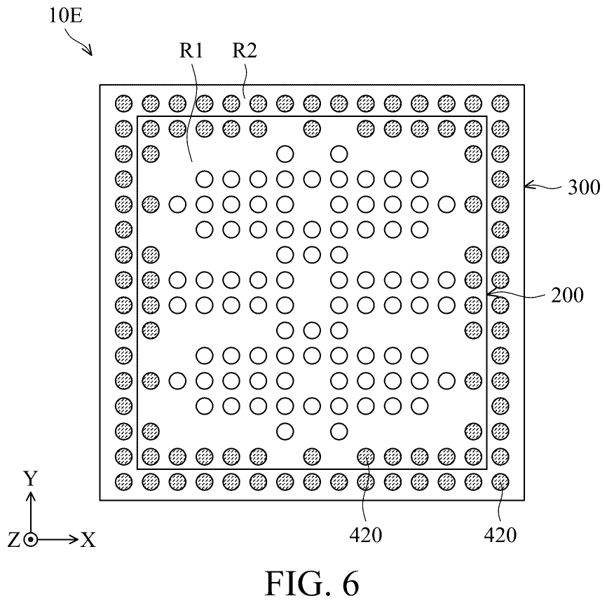

Next, please refer to FIG. 6, which is a top-view diagram of an electronic device 10E in accordance with some embodiments of the present disclosure. It should be understood that, for clarity of explanation, FIG. 6 only schematically illustrates the bonding element 420 and the edges of the chip 200 and the encapsulating layer 300.

As shown in FIG. 6, the electronic device 10E has a first region R1 and a second region R2. The area where the chip 200 overlaps with the circuit structure 400R is defined as the first region R1. The second region R2 surrounds the first region R1. The electronic device 10E includes a plurality of bonding elements 420, and the bonding elements 420 can be disposed in the first region RI and the second region R2. In accordance with some embodiments, the auxiliary pad 410 can be correspondingly disposed on the bonding element 420 around the boundary of the first region R1 and the second region R2 (for clarity of illustration, the bonding elements 420 located around the boundary of the first region R1 and the second region R2 are represented by dots in the figure). Since there is usually relatively large stress at the boundary of the first region R1 and the second region R2, selectively disposing the auxiliary pad 410 at this boundary can reduce the manufacturing cost while improving the stress balance of the electronic device, thereby improving the reliability of the electronic device.

To summarize the above, in accordance with the embodiments of the present disclosure, the electronic device includes an auxiliary pad disposed in a circuit structure. The auxiliary pad can improve the overall stress balance of the connection structures (for example, the connection parts and the bonding elements of the circuit structure) and reduce the stress in the vertical direction when the connection structures are joined, and thereby improving the packaging reliability of the electronic device.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
an electronic component;
an encapsulating layer surrounding the electronic component;
a circuit structure electrically connected to the electronic component, the circuit structure having a connection part;
a bonding element overlapping with the connection part and is electrically connected to the electronic component; and
a first auxiliary pad disposed in the circuit structure,
wherein the connection part is disposed between the first auxiliary pad and the bonding element, the connection part overlaps with the first auxiliary pad, and an intrinsic stress of the first auxiliary pad is between +800 MPa and −1000 MPa.

2. The electronic device as claimed in claim 1, wherein the electronic component comprises:
a chip;
a passivation layer; and
a first insulating layer, wherein the passivation layer is disposed between the chip and the first insulating layer, and a thickness of the first insulating layer is greater than a thickness of the passivation layer.

3. The electronic device as claimed in claim 2, wherein the circuit structure is electrically connected to the chip through a first through hole of the first insulating layer.

4. The electronic device as claimed in claim 2, wherein the chip has an accommodating space, and a portion of the encapsulation layer is disposed in the accommodating space.

5. The electronic device as claimed in claim 3, wherein the circuit structure further comprises:
a second insulating layer disposed between the electronic component and the bonding element, wherein the second insulating layer has a second through hole, and the second through hole overlaps with the first through hole.

6. The electronic device as claimed in claim 1, wherein the circuit structure further comprises:
a patterned conductive layer, wherein the connection part is disposed between the patterned conductive layer and the bonding element.

7. The electronic device as claimed in claim 6, wherein a width of the first auxiliary pad is smaller than a width of the patterned conductive layer.

8. The electronic device as claimed in claim 7, wherein the width of the first auxiliary pad is greater than or equal to 0.3 times the width of the patterned conductive layer, and is less than or equal to 0.6 times the width of the patterned conductive layer.

9. The electronic device as claimed in claim 6, wherein a width of the connection part is greater than or equal to 0.3 times the width of the patterned conductive layer, and is less than or equal to 1.5 times the width of the patterned conductive layer.

10. The electronic device as claimed in claim 1, wherein the circuit structure further comprises:
a second insulating layer disposed between the electronic component and the bonding element.

11. The electronic device as claimed in claim 10, wherein a thermal expansion coefficient of the first auxiliary pad is smaller than a thermal expansion coefficient of the second insulating layer.

12. The electronic device as claimed in claim 10, wherein a Young's modulus of the first auxiliary pad is greater than a Young's modulus of the second insulating layer.

13. The electronic device as claimed in claim 10, wherein the first auxiliary pad is in contact with the second insulating layer.

14. The electronic device as claimed in claim 10, wherein a ratio of a thickness of the first auxiliary pad to a thickness of the second insulating layer is between 0.5 and 1.

15. The electronic device as claimed in claim 1, wherein one end of the bonding element is electrically connected to the connection part, and the other end of the bonding element is electrically connected to an external electronic component.

16. The electronic device as claimed in claim 1, wherein a Young's modulus of the first auxiliary pad is between 220 GPa and 270 GPa.

17. The electronic device as claimed in claim 1, wherein a thermal expansion coefficient of the first auxiliary pad is between 0.1 ppm/K and 12 ppm/K.

18. The electronic device as claimed in claim 1, further comprising:
a second auxiliary pad adjacent to at least one side of the connecting part.

19. The electronic device as claimed in claim 18, wherein a ratio of a thickness of the second auxiliary pad to a thickness of the connecting part is between 0.8 and 1.

20. The electronic device as claimed in claim 18, wherein an intrinsic stress of the second auxiliary pad is between −100 MPa and −1000 MPa.
